(19) United States
(12) Patent Application Publication
(10) Pub. No.: US 2025/0087647 A1
(43) Pub. Date: Mar. 13, 2025

(54) SEMICONDUCTOR PACKAGE

(71) Applicant: Samsung Electronics Co., Ltd., Suwon-si (KR)

(72) Inventors: Jing Cheng LIN, Suwon-si (KR); Youngkun Jee, Suwon-si (KR)

(73) Assignee: Samsung Electronics Co., Ltd., Suwon-si (KR)

(21) Appl. No.: 18/818,203

(22) Filed: Aug. 28, 2024

(30) Foreign Application Priority Data
Sep. 13, 2023 (KR) 10-2023-0122079

(51) Int. Cl. H01L 25/10; H01L 23/00; H01L 23/31; H01L 23/36; H01L 23/498; H01L 23/538; H01L 25/00; H01L 25/16; H01L 25/18; H10B 80/00

(52) U.S. Cl. CPC H01L 25/105; H01L 23/36; H01L 23/49811; H01L 23/5383; H01L 23/3107; H01L 24/16; H01L 24/32; H01L 24/73; H01L 25/16; H01L 25/18; H01L 25/50; H01L 2224/16227; H01L 2224/16238; H01L 2224/32225; H01L 2224/73204; H01L 2225/1041; H10B 80/00

(57) ABSTRACT

A semiconductor package includes a lower redistribution structure, an internal semiconductor chip on the lower redistribution structure and including first connection pads on a lower surface of the internal semiconductor chip, conductive posts connected to the lower redistribution structure, an encapsulant surrounding a side surface of each of the conductive posts, surrounding a side surface of the internal semiconductor chip, and covering an upper surface of the internal semiconductor chip, upper trace pads on the encapsulant and respectively connected to ends of the conductive posts, an external semiconductor device on the encapsulant, the external semiconductor device including second connection pads on a lower surface of the external semiconductor device and respectively connected to the upper trace pads, and a heat dissipation structure on the encapsulant and laterally spaced apart from the external semiconductor device.

### CROSS-REFERENCE TO RELATED APPLICATION

This application is based on and claims priority under 35 U.S.C. § 119 to Korean Patent Application No. 10-2023-0122079, filed on Sep. 13, 2023, in the Korean Intellectual Property Office, the disclosure of which is incorporated by reference herein in its entirety.

### BACKGROUND

Example embodiments of the disclosure relate to a semiconductor package, and more particularly, to a fan-out semiconductor package.

With the rapid development of the electronics industry and user demands, electronic devices are becoming more compact and multi-functional, and are increasing in capacity. Accordingly, highly integrated semiconductor chips are required. Therefore, semiconductor packages including connection terminals with connection reliability are being designed for highly integrated semiconductor chips including an increased number of connection terminals for input/output (I/O). For example, fan-out semiconductor packages having increased spacing between connection terminals are being developed to prevent interference between connection terminals.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package with improved thermal characteristics by improving heat dissipation characteristics of an internal semiconductor chip.

Additional aspects will be set forth in part in the description which follows and, in part, will be apparent from the description, or may be learned by practice of the presented embodiments.

According to an aspect of an example embodiment, a semiconductor package may include a lower redistribution structure, an internal semiconductor chip on the lower redistribution structure and including first connection pads on a lower surface of the internal semiconductor chip, conductive posts connected to the lower redistribution structure, an encapsulant surrounding a side surface of each of the conductive posts, surrounding a side surface of the internal semiconductor chip, and covering an upper surface of the internal semiconductor chip, upper trace pads on the encapsulant and respectively connected to ends of the conductive posts, an external semiconductor device on the encapsulant, the external semiconductor device including second connection pads on a lower surface of the external semiconductor device and respectively connected to the upper trace pads, a heat dissipation structure on the encapsulant and laterally spaced apart from the external semiconductor device, and a heat transfer layer on a lower surface of the heat dissipation structure, the heat transfer layer including a thermal interface material, where the heat dissipation structure is above the internal semiconductor chip.

According to an aspect of an example embodiment, a semiconductor package may include a lower redistribution structure, an internal semiconductor chip on the lower redistribution structure and including first connection pads on a lower surface of the internal semiconductor chip, a core layer on the lower redistribution structure and laterally spaced apart from the internal semiconductor chip, the core layer including a core insulating layer, core vias passing through the core insulating layer, and core wiring layers, an encapsulant at least partially surrounding the internal semiconductor chip and the core layer, upper trace pads on the encapsulant, an external semiconductor device on the encapsulant, the external semiconductor device including second connection pads on a lower surface of the external semiconductor device and respectively connected to the upper trace pads, a heat dissipation structure on the encapsulant and laterally spaced apart from the external semiconductor device, and a heat transfer layer on a lower surface of the heat dissipation structure, the heat transfer layer including a thermal interface material, where the heat dissipation structure is above the internal semiconductor chip.

According to an aspect of an example embodiment, a semiconductor package may include a lower redistribution structure, an internal semiconductor chip on the lower redistribution structure and including first connection pads on a lower surface of the internal semiconductor chip, conductive posts connected to the lower redistribution structure, an encapsulant surrounding a side surface of each of the conductive posts, surrounding a side surface of the internal semiconductor chip, and covering an upper surface of the internal semiconductor chip, upper trace pads on the encapsulant and respectively connected to ends of the conductive posts, an external semiconductor device on the encapsulant, the external semiconductor device including second connection pads on a lower surface of the external semiconductor device and respectively connected to the upper trace pads, a heat dissipation structure on the encapsulant and laterally spaced apart from the external semiconductor device, and a heat transfer layer on a lower surface of the heat dissipation structure, the heat transfer layer including a thermal interface material, where the heat dissipation structure is above the internal semiconductor chip, the conductive posts are laterally spaced apart from a first side of the internal semiconductor chip and are not provided relative to a second side of the internal semiconductor chip that is opposite the first side of the internal semiconductor chip, an upper surface of each of the conductive posts is coplanar with an upper surface of the encapsulant, at least some of the upper trace pads horizontally extend on the encapsulant from the conductive posts, at least one second connection pad of the second connection pads is laterally offset from at least one conductive post of the conductive posts that is connected to the at least one second connection pad, the encapsulant includes a first encapsulant and a second encapsulant which are integrally formed, an upper surface of the first encapsulant is at a vertical level that is higher than a vertical level of an upper surface of the second encapsulant, the upper trace pads are on the upper surface of the first encapsulant, the upper surface of the second encapsulant is coplanar with the upper surface of the internal semiconductor chip, a horizontal width of the heat dissipation structure is greater than a horizontal width of the internal semiconductor chip, and a vertical level of an upper surface of the heat dissipation structure is lower than or equal to a vertical level of an upper surface of the external semiconductor device.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1A is a cross-sectional view illustrating a semiconductor package according to one or more example embodiments;

FIG. 1B is a plan view taken along line A-A′ of FIG. 1A according to one or more example embodiments;

FIG. 2A is a cross-sectional view illustrating a semiconductor package according to one or more example embodiments;

FIG. 2B is a plan view taken along line B-B′ of FIG. 2A according to one or more example embodiments;

FIG. 3 is a cross-sectional view illustrating a semiconductor package according to one or more example embodiments;

FIG. 4A is a cross-sectional view illustrating a semiconductor package according to one or more example embodiments;

FIG. 4B is a plan view taken along line C-C′ of FIG. 4A according to one or more example embodiments;

FIG. 5A is a cross-sectional view illustrating a semiconductor package according to one or more example embodiments;

FIG. 5B is a plan view taken along line D-D′ of FIG. 5B according to one or more example embodiments;

FIG. 6 is a cross-sectional view illustrating a semiconductor package according to one or more example embodiments;

FIG. 7 is a cross-sectional view illustrating a semiconductor package according to one or more example embodiments;

FIG. 8 is a cross-sectional view illustrating a semiconductor package according to one or more example embodiments;

FIG. 9 is a cross-sectional view illustrating a semiconductor package according to one or more example embodiments;

FIGS. 10A to 10I are cross-sectional views sequentially illustrating a method of manufacturing a semiconductor package, according to one or more example embodiments; and

FIGS. 11A to 11J are cross-sectional views sequentially illustrating a method of

manufacturing a semiconductor package, according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

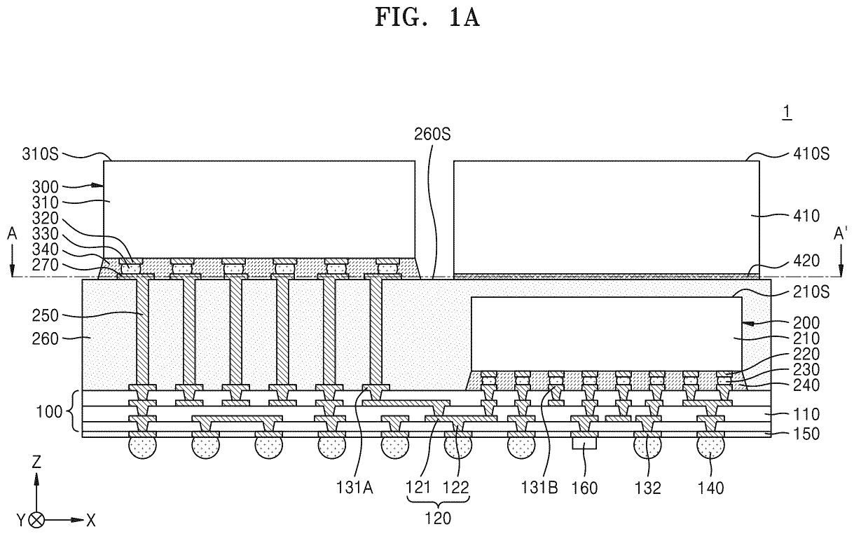

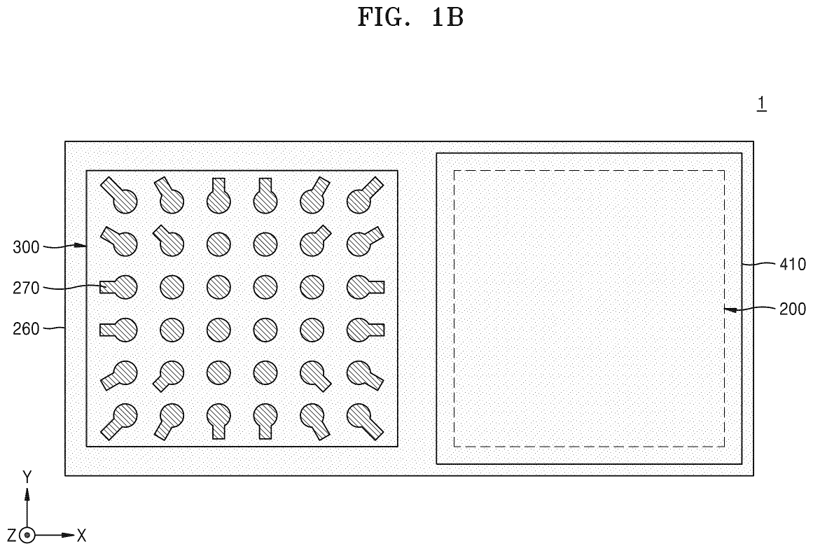

FIG. 1A is a cross-sectional view illustrating a semiconductor package according to one or more example embodiments. FIG. 1B is a plan view taken along line A-A′ of FIG. 1A according to one or more example embodiments.

Referring to FIGS. 1A and 1B, the semiconductor package 1 may include a lower redistribution structure 100, an internal semiconductor chip 200 mounted on the lower redistribution structure 100, conductive posts 250 arranged on a side of the internal semiconductor chip 200 and spaced apart from the internal semiconductor chip 200, an encapsulant 260 surrounding side surfaces of the conductive posts 250, as well as an upper surface (i.e., covering the upper surface) and a side surface of the internal semiconductor chip 200, an external semiconductor device 300 arranged on the encapsulant 260 and electrically connected to the conductive posts 250, and a heat dissipation structure 410 on an upper surface of the encapsulant 260.

The semiconductor package 1 may be a fan-out semiconductor package in which a horizontal width and a horizontal area of the lower redistribution structure 100 are greater than a horizontal width and a horizontal area of the internal semiconductor chip 200. In example embodiments, the semiconductor package 1 may be a fan-out wafer level package (FOWLP) or a fan-out panel level package (FOPLP). An embodiment in which the semiconductor package 1 is an FOPLP is described below.

In some embodiments, the lower redistribution structure 100 may be formed through a redistribution process. The lower redistribution structure 100 may include a redistribution insulating layer 110 and a plurality of redistribution patterns 120. The redistribution insulating layer 110 may at least partially surround the plurality of redistribution patterns 120. In some embodiments, the lower redistribution structure 100 may include a plurality of redistribution insulating layers 110 that are stacked. The redistribution insulating layer 110 may be formed of, for example, photo imageable dielectric (PID) or photosensitive polyimide (PSPI).

A passivation layer 150 may be provided on a lower surface of the lower redistribution structure 100. The passivation layer 150 that protects the lower redistribution structure 100 may be formed of polymer and may cover at least a portion of a side surface and a lower surface of each of a plurality of external connection pads 132.

The plurality of redistribution patterns 120 may include a plurality of redistribution line patterns 121 and a plurality of redistribution via patterns 122. The plurality of redistribution patterns 120 may be formed of any one of metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy of the metals but are not limited thereto.

The plurality of redistribution line patterns 121 may be on at least one of an upper surface and a lower surface of the redistribution insulating layer 110. For example, when the lower redistribution structure 100 includes the plurality of stacked redistribution insulating layers 110, the plurality of redistribution line patterns 121 may be between an upper surface of the uppermost one of the redistribution insulating layers 110, a lower surface of the lowermost one of the redistribution insulating layers 110, and the redistribution insulating layer 110 adjacent thereto.

The plurality of redistribution via patterns 122 may pass through the redistribution insulating layer 110 to be respectively connected to some of the plurality of redistribution line patterns 121. In some embodiments, each of the plurality of redistribution via patterns 122 may have a tapered shape having a horizontal width that increases towards the encapsulant 260.

In some embodiments, some of the plurality of redistribution line patterns 121 may be respectively formed together with some of the plurality of redistribution via patterns 122 to form one body. For example, the redistribution line pattern 121 and the redistribution via pattern 122 contacting a lower surface of the redistribution line pattern 121 may be formed together to form one body.

Among the plurality of redistribution patterns 120, some redistribution patterns adjacent to a lower surface of the lower redistribution structure 100 may be referred to as a plurality of external connection pads 132, and some redistribution patterns adjacent an upper surface of the lower redistribution structure 100 may be referred to as a plurality of first upper connection pads 131A and a plurality of second upper connection pads 131B. Also, the plurality of external connection pads 132 may be some of the plurality of redistribution line patterns 121 which are adjacent to a lower surface of the lower redistribution structure 100, and the plurality of first upper connection pads 131A and the plurality of second upper connection pads 131B may be some of the plurality of redistribution line patterns 121 which are adjacent to an upper surface of the lower redistribution structure 100.

A plurality of external connection terminals 140 may be respectively attached to the plurality of external connection pads 132. The plurality of external connection terminals 140 may connect the semiconductor package 1 to an external device. In some embodiments, the plurality of external connection terminals 140 may be solder bumps or solder balls. In some embodiments, a plurality of first connection members 230 may be attached to some of the plurality of first upper connection pads 131A and the plurality of second upper connection pads 131B, and a plurality of conductive posts 250 may be connected to the others of the plurality of first upper connection pads 131A and the plurality of second upper connection pads 131B. For example, the plurality of conductive posts 250 may be respectively arranged on the plurality of first upper connection pads 131A, and a plurality of first connection members 230 may be respectively arranged on the plurality of second upper connection pads 131B. Sizes and pitches of the plurality of second upper connection pads 131B may be less than sizes and pitches of the plurality of first upper connection pads 131A.

A passive element 160 may be attached to each of the plurality of external connection pads 132. The passive element 160 may be electrically connected to the internal semiconductor chip 200 through the lower redistribution structure 100 to. The passive element 160 may include a capacitor, a resistor, an inductor, or so on, and unlike FIG. 1, the passive element 160 may include a plurality of passive elements.

The plurality of first upper connection pads 131A and the plurality of second upper connection pads 131B may be on an upper surface of the redistribution insulating layer 110. For example, when the lower redistribution structure 100 includes a plurality of stacked redistribution insulating layers 110, the plurality of first upper connection pads 131A and the plurality of second upper connection pads 131B may be on an upper surface of the uppermost redistribution insulating layer 110.

At least one internal semiconductor chip 200 may be mounted on the lower redistribution structure 100. That is, the internal semiconductor chip 200 may be composed of a single internal semiconductor chip or a plurality of internal semiconductor chips. The internal semiconductor chip 200 may include a semiconductor substrate 210 and a plurality of first connection pads 220 on a lower surface of the semiconductor substrate 210. For example, the internal semiconductor chip 200 may have a vertical thickness of about 150 μm or more. A lower surface of the internal semiconductor chip 200 may refer to a surface facing the lower redistribution structure 100, and an upper surface of the internal semiconductor chip 200 may refer to a surface opposite to the lower surface of the internal semiconductor chip 200. In some embodiments, a face-down arrangement is provided in which an active surface on which components of the internal semiconductor chip 200 are arranged faces the lower redistribution structure 100, and the internal semiconductor chip 200 may be mounted on an upper surface of the lower redistribution structure 100. The plurality of first connection pads 220 may be pads or studs.

The plurality of first connection members 230 may be between the plurality of first connection pads 220 of the internal semiconductor chip 200 and some of the plurality of first upper connection pads 131A and the plurality of second upper connection pads 131B of the lower redistribution structure 100. That is, the plurality of first connection members 230 may be between the plurality of second upper connection pads 131B and the plurality of first connection pads 220. For example, each of the plurality of first connection members 230 may be a solder ball or a micro bump. The internal semiconductor chip 200 may be electrically connected to the plurality of redistribution patterns 120 of the lower redistribution structure 100 through the plurality of first connection members 230. The plurality of first connection members 230 may each be formed of, for example, copper (Cu), aluminum (Al), silver (Ag), tin (Tin), gold (Au), or solder but are not limited thereto.

For example, the semiconductor substrate 210 may include a semiconductor material, such as silicon (Si) or germanium (Ge). Alternatively, the semiconductor substrate 210 may include a compound semiconductor material, such as silicon carbide (SiC), gallium arsenide (GaAs), indium arsenide (InAs), or indium phosphide (InP). The semiconductor substrate 210 may include a well doped with an impurity, which is a conductive region. The semiconductor substrate 210 may have various device isolation structures, such as a shallow trench isolation (STI) structure.

A semiconductor device including a plurality of individual devices of various types may be formed on an active surface of the semiconductor substrate 210. The plurality of individual devices may be electrically connected to a conductive region of the semiconductor substrate 210. The semiconductor device may further include conductive wires or conductive plugs that respectively and electrically connect the plurality of individual devices to the conductive region of the semiconductor substrate 210. Also, each of the plurality of individual devices may be electrically spaced apart from other adjacent individual devices by an insulating film.

In some embodiments, the internal semiconductor chip 200 may include logic elements. For example, the internal semiconductor chip 200 may be a central processing unit (CPU) chip, a graphics processing unit (GPU) chip, or an application processor (AP) chip. In some embodiments, when the semiconductor package 1 includes a plurality of internal semiconductor chips 200, one of the plurality of internal semiconductor chips 200 may be a CPU chip, a GPU chip, or an AP chip, and another of the plurality of internal semiconductor chips may be a semiconductor memory chip including a memory device.

For example, the memory device may be a nonvolatile memory device, such as flash memory, phase-change random access memory (PRAM), magnetoresistive random access memory (MRAM), ferroelectric random access memory (FeRAM), or resistive random access memory (RRAM). In some embodiments, the memory device may be a volatile memory device, such as dynamic random access memory (DRAM) or static random access memory (SRAM).

In some embodiments, the internal semiconductor chip 200 may be a semiconductor device in which a plurality of semiconductor chips are stacked vertically. The plurality of semiconductor chips may be stacked semiconductor chips including through silicon vias (TSVs).

The encapsulant 260 may surround the internal semiconductor chip 200 and the conductive posts 250 on an upper surface of the lower redistribution structure 100. An upper surface 260S of the encapsulant 260 may have a flat plane shape. The external semiconductor device 300 and the heat dissipation structure 410 may be on the upper surface 260S of the encapsulant 260. A vertical level of the upper surface 260S of the encapsulant 260 measured from the lower redistribution structure 100 may be higher than a vertical level of an upper surface 210S of the internal semiconductor chip 200 measured from the lower redistribution structure 100. Accordingly, the encapsulant 260 may be on the upper surface 210S of the internal semiconductor chip 200.

A plurality of upper trace pads 270 may be on the upper surface 260S of the encapsulant 260 and respectively and electrically connect the plurality of conductive posts 250 to the external semiconductor device 300, and the plurality of conductive posts 250 may be respectively connected to the plurality of upper trace pads 270. For example, the encapsulant 260 may have a thickness of about 150 μm to about 500 μm. For example, the encapsulant 260 may be a molding member including epoxy mold compound (EMC). The encapsulant 260 may further include a filler.

In some embodiments, an internal underfill layer 240 surrounding the plurality of first connection members 230 may be between the internal semiconductor chip 200 and the lower redistribution structure 100. In some embodiments, the internal underfill layer 240 may fill a space between the internal semiconductor chip 200 and the lower redistribution structure 100 and cover a lower portion of a side surface of the internal semiconductor chip 200 or cover a lower surface of the internal semiconductor chip 200. For example, the internal underfill layer 240 may be formed through a capillary underfill process and may be formed of epoxy resin.

In some embodiments, a side surface of the lower redistribution structure 100 may be aligned in a vertical direction and may be substantially coplanar with a side surface of the encapsulant 260.

The plurality of conductive posts 250 may pass through the encapsulant 260 to electrically connect the lower redistribution structure 100 to the external semiconductor device 300. The encapsulant 260 may surround side surfaces of the plurality of conductive posts 250.

The plurality of conductive posts 250 may be on a side of the internal semiconductor chip 200 and spaced apart from the internal semiconductor chip 200. The plurality of conductive posts 250 may be on an upper surface of the lower redistribution structure 100. The plurality of conductive posts 250 may be between the lower redistribution structure 100 and the external semiconductor device 300. The plurality of conductive posts 250 may be at a side of the internal semiconductor chip 200 to be spaced apart from the internal semiconductor chip 200 without being on both sides of the internal semiconductor chip 200. That is, no conductive posts 250 may be on the opposite side (e.g., the right side in FIG. 1A) of the internal semiconductor chip 200.

In one embodiment, as illustrated in FIGS. 1A and 1B, the plurality of conductive posts 250 may be spaced apart from the internal semiconductor chip 200 in the first direction (the X direction), without being dispersed around the circumference of the internal semiconductor chip 200, and may be grouped together on one side of the internal semiconductor chip 200. In the semiconductor package 1 according to some embodiments, no additional upper redistribution structure is provided on an upper surface of the encapsulant 260, and the external semiconductor device 300 may be electrically connected the lower redistribution structure 100. Accordingly, the plurality of conductive posts 250 may be below the external semiconductor device 300.

The plurality of conductive posts 250 may be between the plurality of first upper connection pads 131A and the plurality of upper trace pads 270 to be described below. Lower surfaces of the plurality of conductive posts 250 may be respectively and electrically connected to the plurality of redistribution patterns 120 by contacting the plurality of first upper connection pads 131A of the lower redistribution structure 100. Upper surfaces of the plurality of conductive posts 250 may be electrically connected to the external semiconductor device 300 mounted on the encapsulant 260 by contacting the plurality of upper trace pads 270.

For example, a vertical length of each of the plurality of conductive posts 250 may be about 200 μm to about 500 μm, and a horizontal width of each of the plurality of conductive posts 250 may be about 120 μm to about 200 μm. An aspect ratio of each of the plurality of conductive posts 250 (that is, a ratio of a height to the horizontal width) may be greater than 1. In some embodiments, the plurality of conductive posts 250 may each include copper (Cu) or a copper alloy but are not limited thereto.

An upper surface 260S of the encapsulant 260 may be substantially coplanar with one upper surface of each of the plurality of conductive posts 250. The plurality of upper trace pads 270 respectively connected to the plurality of conductive post 250 may be on the upper surface 260S of the encapsulant 260.

When an arrangement of the plurality of conductive posts 250 does not match an arrangement of the plurality of second connection pads 320 provided in the external semiconductor device 300, the plurality of upper trace pads 270 may extend toward the plurality of second connection pads 320, as illustrated in FIG. 1B, such that the plurality of conductive posts 250 and the plurality of second connection pads 320, which have to be respectively connected to each other, may be connected to each other.

For example, as illustrated in FIG. 1B, some of the plurality of upper trace pads 270 arranged at a central portion may not extend in one direction. In contrast, some of the plurality of upper trace pads 270 respectively arranged on the outside may extend in one direction. Some of the plurality of upper trace pads 270 respectively arranged on the outside may extend radially outward from some of the plurality of upper trace pads 270 arranged at a central portion. For example, some of the plurality of upper trace pads 270 arranged at the upper left may extend from the center to the upper left. However, the semiconductor package 1 according to the embodiment is not limited to the extensions and extension\directions of the plurality of upper trace pads 270.

The plurality of upper trace pads 270 may be connected to the plurality of second connection pads 320 of the external semiconductor device 300. The plurality of upper trace pads 270 may be respectively and electrically connected to the plurality of conductive posts 250. However, the plurality of conductive posts 250 may be misaligned on a horizontal plane with the plurality of second connection pads 320 of the external semiconductor device 300 that are to be electrically connected to the plurality of conductive posts 250. That is, the plurality of second connection pads 320 that are to be electrically connected to the plurality of conductive posts 250 may be offset in a horizontal direction from the plurality of conductive posts 250 corresponding thereto. The plurality of upper trace pads 270 may extend from the plurality of conductive posts 250 to be under the plurality of second connection pads 320 such that the plurality of second connection pads 320, which are horizontally offset from the plurality of conductive posts 250, are electrically connected to the plurality of conductive posts 250, and a plurality of second connection members 330 may be between the plurality of upper trace pads 270 and the plurality of second connection pads 320.

In some embodiments, an external underfill layer 340 at least partially surrounding the plurality of second connection members 330 may be between the external semiconductor device 300 and the encapsulant 260. In some embodiments, the external underfill layer 340 may fill a space between the internal semiconductor chip 200 and the encapsulant 260, and may cover a portion of a lower portion of a side surface of the external semiconductor device 300 or cover a lower surface of the external semiconductor device 300. The external underfill layer 340 may be formed through, for example, a capillary underfill process and may be formed of epoxy resin.

The external semiconductor device 300 may include an external semiconductor body 310 and the plurality of second connection pads 320 on a lower surface of the external semiconductor body 310. The external semiconductor body 310 may refer to a single semiconductor chip or may refer to a plurality of semiconductor chips stacked together. The external semiconductor device 300 may include logic elements. For example, the external semiconductor device 300 may be a CPU chip, a GPU chip, or an AP chip. In some embodiments, when the external semiconductor device 300 includes a plurality of semiconductor chips, one of the plurality of semiconductor chips included in the external semiconductor device 300 may be a CPU chip, a GPU chip, or an AP chip, and another of the plurality of semiconductor chips may be a semiconductor memory chip including a memory device.

For example, the memory device may be a nonvolatile memory device, such as flash memory, PRAM, MRAM, FeRAM, or RRAM. In some embodiments, the memory device may be a volatile memory device, such as DRAM or SRAM.

In some embodiments, the external semiconductor device 300 may be a semiconductor device in which a plurality of semiconductor chips are stacked vertically. The plurality of semiconductor chips may be stacked semiconductor chips including TSVs. For example, the external semiconductor device 300 may be a high bandwidth memory (HBM) device.

The heat dissipation structure 410 may be provided relative to a side of the external semiconductor device 300 and vertically spaced apart from the internal semiconductor chip 200. The heat dissipation structure 410 may be on the encapsulant 260. A heat transfer layer 420 may be between the heat dissipation structure 410 and the encapsulant 260. A planar area of the heat transfer layer 420 may be the same as or greater than a planar area of the heat dissipation structure 410. As illustrated in FIG. 1B, a planar area of the heat dissipation structure 410 may be greater than a planar area of the internal semiconductor chip 200. The heat dissipation structure 410 may include silicon or include at least one of aluminum (Al), copper (Cu), titanium (Ti), nickel (Ni), iron (Fe), cobalt (Co), palladium (Pd), or platinum (Pt), gold (Au), lead (Pb), platinum (Pt), silver (Ag), carbon (C), tin (Sn), tungsten (W), and chromium (Cr), or a metal including an alloy thereof.

The heat transfer layer 420 may include a thermal interface material (TIM). The heat transfer layer 420 may have a higher heat transfer rate than a general adhesive material. By attaching the heat dissipation structure 410 to the upper surface 260S of the encapsulant 260, the heat transfer layer 420 may receive the heat which is generated by the internal semiconductor chip 200 and transferred to the encapsulant 260. The heat transfer layer 420 may have a structure in which fillers, such as metal particles, are dispersed in a polymer material. A TIM may include, for example, mineral oil, grease, gap filler putty, phase change gel, phase change material pads, or particle-filled epoxy.

The heat generated by the internal semiconductor chip 200 may be transferred to the surroundings through the encapsulant 260 contacting the upper surface 210S of the internal semiconductor chip 200. A conventional semiconductor package equipped with an external semiconductor device requires an upper redistribution structure for mounting the external semiconductor device. In a conventional semiconductor package, it is difficult for the heat generated by the internal semiconductor chip 200 to be smoothly dissipated due to the upper redistribution structure on an upper portion of the encapsulant 260.

The semiconductor package 1 according to some embodiments may have a structure in which the plurality of upper trace pads 270 are arranged on an upper surface of the encapsulant 260 and the plurality of conductive posts 250 are concentrated on one side of the internal semiconductor chip 200 to be spaced apart from the internal semiconductor chip 200. That is, an electrical connection of the conductive post 250, the upper trace pad 270, and the external semiconductor device 300 may be made and the semiconductor package 1 may not include an upper redistribution structure.

According to some embodiments of the disclosure, the semiconductor package 1 does not include an upper redistribution structure and the external semiconductor device 300 is mounted on the semiconductor package 1. Thus, the heat generated by the internal semiconductor chip 200 may be smoothly dissipated. Also, by providing the heat dissipation structure 410 on the upper surface 260S of the encapsulant 260 above the internal semiconductor chip 200, the heat generated by the internal semiconductor chip 200 may be transferred to the heat dissipation structure 410, and thus, heat dissipation of the internal semiconductor chip 200 may be made more smoothly. Accordingly, heat dissipation characteristics of the semiconductor package 1 according to some embodiments may be improved.

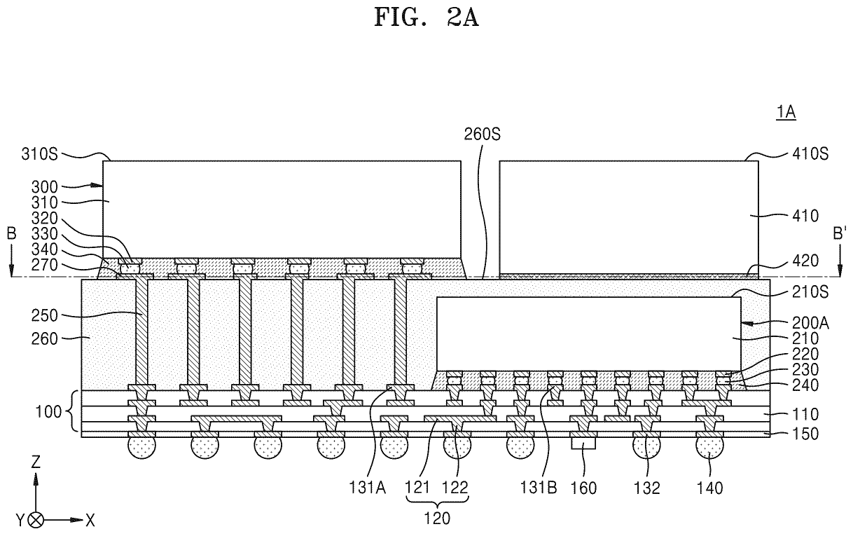

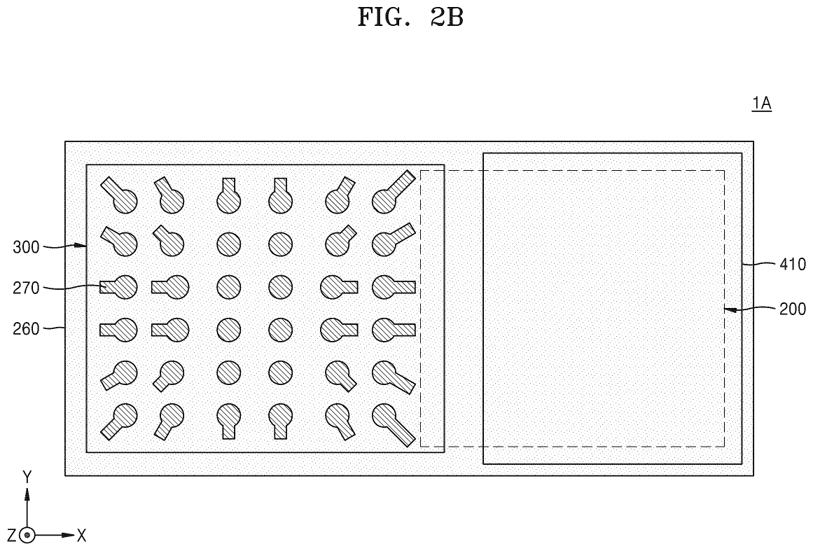

FIG. 2A is a cross-sectional view illustrating a semiconductor package according to one or more example embodiments. FIG. 2B is a plan view taken along line B-B′ of FIG. 2A according to one or more example embodiments. Descriptions similar to the descriptions given with reference to FIGS. 1A and 1B may be omitted.

Referring to FIGS. 2A and 2B, a planar area of an internal semiconductor chip 200A of the semiconductor package 1A illustrated in FIGS. 2A and 2B may be greater than a planar are of the internal semiconductor chip 200 of the semiconductor package 1 illustrated in FIGS. 1A and 1B. Also, a planar are of an external semiconductor device 300 of the semiconductor package 1A illustrated in FIGS. 2A and 2B may be greater than a planar area of the external semiconductor device 300 of the semiconductor package 1 illustrated in FIGS. 1A and 1B. Accordingly, a portion of the external semiconductor device 300 may overlap a portion of the internal semiconductor chip 200A. In other words, a portion of the external semiconductor device 300 that is above the lower redistribution structure 100 may overlap a portion of the internal semiconductor chip 200 that is above the lower redistribution structure 100.

Offsets in the horizontal direction between some of the plurality of second connection pads 320 included in the external semiconductor device 300 and some of the plurality of conductive posts 250 electrically connected to some of the plurality of second connection pads 320 may be increased. The plurality of upper trace pads 270 may respectively and electrically connect some of the plurality of second connection pads 320 to some of the plurality of conductive posts 250 electrically connected to some of the plurality of second connection pads 320.

The heat dissipation structure 410 may be attached to the encapsulant 260 through the heat transfer layer 420. A size of the heat dissipation structure 410 may be appropriately selected depending on a size and shape of the internal semiconductor chip 200A, a size and shape of the external semiconductor device 300, the amount of heat generated by the internal semiconductor chip 200A, and heat dissipation requirements/preferences of the internal semiconductor chip 200A. For example, in the semiconductor package 1A according to some embodiments, the heat dissipation structure 410 may be on a side of the external semiconductor device 300 and spaced apart from the external semiconductor device 300. Therefore, as illustrated in FIG. 2B, in a plan view, the external semiconductor device 300 and the heat dissipation structure 410 include a portion that overlaps the internal semiconductor chip 200, and the internal semiconductor chip 200 may include a portion that is not overlapped by both the external semiconductor device 300 and the heat dissipation structure 410.

As illustrated in FIG. 2B, a length of the heat dissipation structure 410 in a first direction (the X direction) may be less than a length of the internal semiconductor chip 200A in the first direction (the X direction). Also, a length of the heat dissipation structure 410 in a second direction (the Y direction) may be greater than a length the internal semiconductor chip 200A in the second direction (the Y direction).

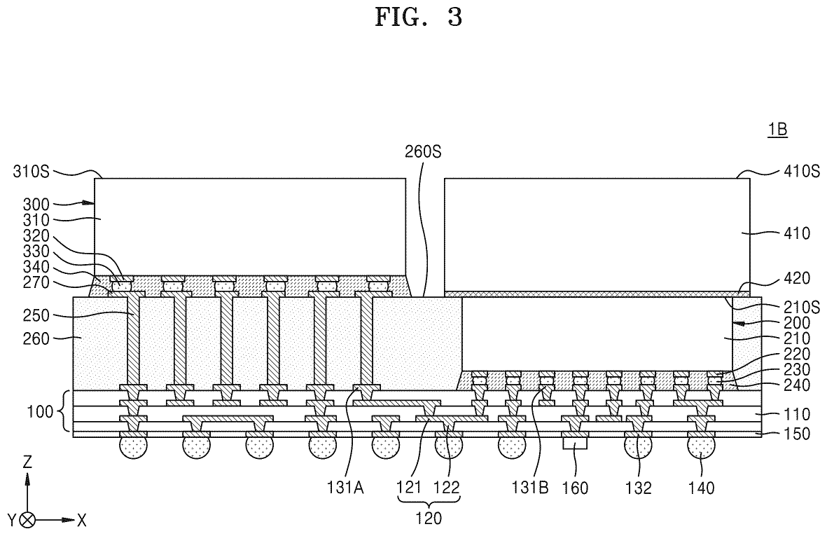

FIG. 3 is a cross-sectional view illustrating a semiconductor package according to one or more example embodiments. Descriptions similar to the descriptions given with reference to FIGS. 1A to 2B may be omitted.

Referring to FIG. 3, the upper surface 260S of the encapsulant 260 may be substantially coplanar with the upper surface 210S of the internal semiconductor chip 200. In other words, a vertical level of the upper surface 260S of the encapsulant 260 may be equal to a vertical level of the upper surface 210S of the internal semiconductor chip 200. Accordingly, the upper surface 210S of the internal semiconductor chip 200 is not covered by the encapsulant 260, and thereby, the heat dissipation structure 410 may be directly on the upper surface 210S of the internal semiconductor chip 200. The heat transfer layer 420 may be between the internal semiconductor chip 200 and a portion of the encapsulant 260, and the heat dissipation structure 410.

A vertical level of the upper surface 410S of the heat dissipation structure 410 may be lower than or equal to a vertical level of the upper surface 310S of the external semiconductor device 300. For example, as illustrated in FIG. 3, the vertical level of the upper surface 410S of the heat dissipation structure 410 may be equal to a vertical level of the upper surface 310S of the external semiconductor device 300.

The semiconductor package 1B according to some embodiments does not include an upper redistribution structure, and the external semiconductor device 300 is mounted on the semiconductor package 1B. Accordingly, the heat generated by the internal semiconductor chip 200 may be smoothly dissipated. Also, by providing the heat dissipation structure 410 on the upper surface 210S of the internal semiconductor chip 200, the heat generated by the internal semiconductor chip 200 may be transferred to the heat dissipation structure 410, and thus, heat dissipation of the internal semiconductor chip 200 may be made more smoothly. Accordingly, heat dissipation characteristics of the semiconductor package 1B according to some embodiments may be improved.

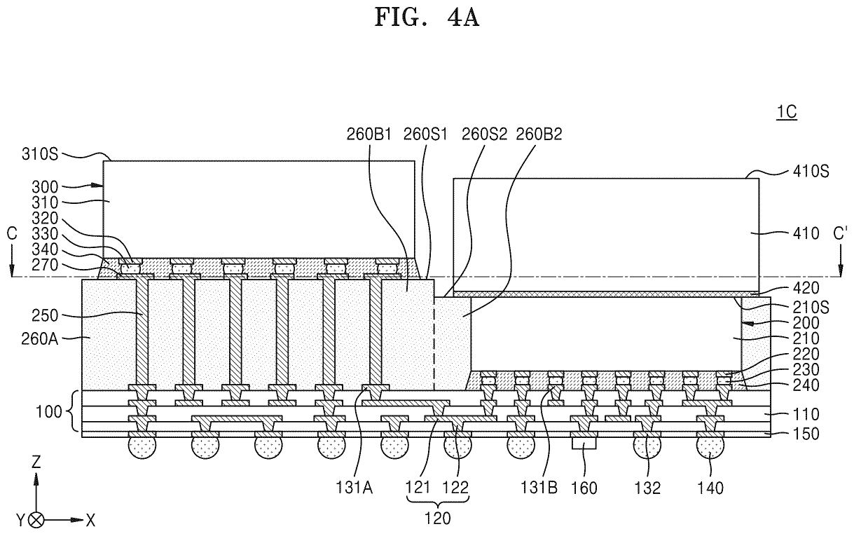

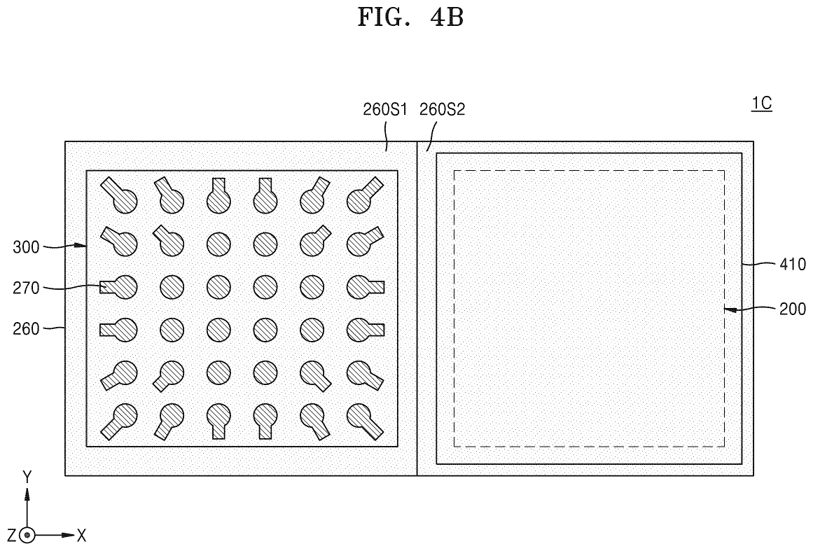

FIG. 4A is a cross-sectional view illustrating a semiconductor package according to one or more example embodiments. FIG. 4B is a plan view taken along line C-C′ of FIG. 4A according to one or more example embodiments. Descriptions similar to the descriptions given with reference to FIGS. 1A to 3B may be omitted.

Referring to FIGS. 4A and 4B, an encapsulant 260A may include a first encapsulant 260B1 and a second encapsulant 260B2. The first encapsulant 260B1 and the second encapsulant 260B2 may be on the lower redistribution structure 100 as one body (i.e., may be integrally formed). A first upper surface 260S1 of the first encapsulant 260B1 may not be coplanar with a second upper surface 260S2 of the second encapsulant 260B2. That is, a vertical level of the first upper surface 260S1 of the first encapsulant 260B1 may be different from a vertical level of the second upper surface 260S2 of the second encapsulant 260B2. For example, as illustrated in FIG. 4A, the vertical level of the first upper surface 260S1 of the first encapsulant 260B1 may be higher than the vertical level of the second upper surface 260S2 of the second encapsulant 260B2. The vertical dashed line displayed between the first encapsulant 260B1 and the second encapsulant 260B2 is provided for illustration to distinguish the first encapsulant 260B1 from the second encapsulant 260B2.

The encapsulant 260A of the semiconductor package 1C according to some embodiments may be formed through a process of forming a first encapsulant and then removing a portion to be formed as the second encapsulant 260B2 such that the vertical level of the first upper surface 260S1 of the first encapsulant 260B1 is different from the vertical level of the second upper surface 260S2 of the second encapsulant 260B2.

The second upper surface 260S2 may be substantially coplanar with the upper surface 210S of the internal semiconductor chip 200. In other words, the vertical level of the second upper surface 260S2 may be equal to the vertical level of the upper surface 210S of the internal semiconductor chip 200. The encapsulant 260A may not cover the upper surface 210S of the internal semiconductor chip 200. Accordingly, the heat dissipation structure 410 may be directly on the upper surface 210S of the internal semiconductor chip 200. In order to smoothly transfer heat between the heat dissipation structure 410 and the internal semiconductor chip 200, a heat transfer layer 420 may be between the heat dissipation structure 410 and the internal semiconductor chip 200.

In the semiconductor package 1C according to some embodiments, a portion of the encapsulant 260A may be removed to cause the vertical level of the first upper surface 260S1 to be different from the vertical level of the second upper surface 260S2. Accordingly, the vertical level of the second upper surface 260S2 may be equal to the vertical level of the upper surface 210S of the internal semiconductor chip 200, and thereby, the heat dissipation structure 410 may be directly on the internal semiconductor chip 200. The vertical level of the upper surface 410S of the heat dissipation structure 410 may be equal to or lower than the vertical level of the upper surface 310S of the external semiconductor device 300. For example, as illustrated in FIG. 4A, the vertical level of the upper surface 410S of the heat dissipation structure 410 may be lower than the vertical level of the upper surface 310S of the external semiconductor device 300.

As the heat dissipation structure 410 is directly on the internal semiconductor chip 200, the heat generated by the internal semiconductor chip 200 may be more effectively transferred to the heat dissipation structure 410, and thus, the heat generated by the internal semiconductor chip 200 may be dissipated more easily. Accordingly, heat dissipation characteristics of the semiconductor package 1C according to some embodiments may be improved.

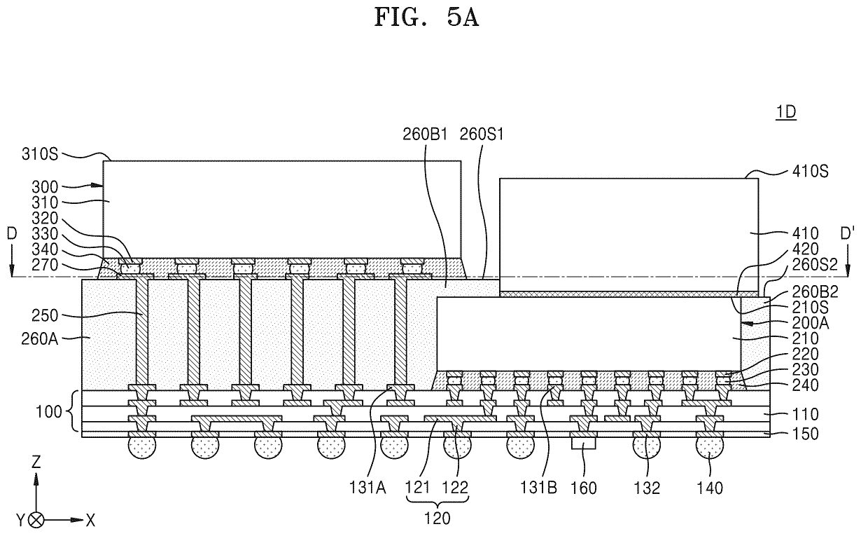

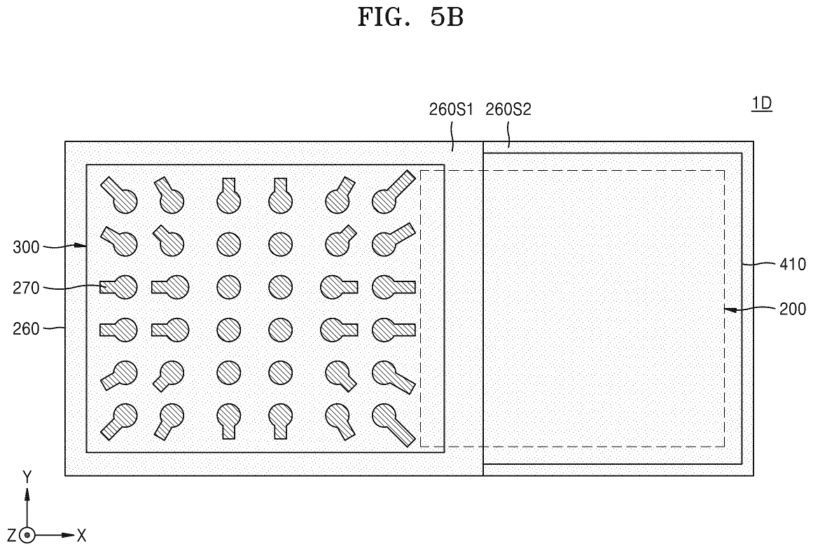

FIG. 5A is a cross-sectional view illustrating a semiconductor package according to one or more example embodiments. FIG. 5B is a plan view taken along line D-D′ of FIG. 5B according to one or more example embodiments. Descriptions similar to the descriptions given with reference to FIGS. 1A to 4B may be omitted.

Referring to FIGS. 5A and 5B, the first encapsulant 260B1 may contact a portion of a side surface of the heat dissipation structure 410. Also, the second upper surface 260S2 may be substantially coplanar with the upper surface 210S of the internal semiconductor chip 200. In other words, a vertical level of the second upper surface 260S2 may be equal to a vertical level of the upper surface 210S of the internal semiconductor chip 200. The encapsulant 260A may not cover the upper surface 210S of the internal semiconductor chip 200. Accordingly, the heat dissipation structure 410 may be directly on the upper surface 210S of the internal semiconductor chip 200. In order to smoothly transfer heat between the heat dissipation structure 410 and the internal semiconductor chip 200, a heat transfer layer 420 may be between the heat dissipation structure 410 and the internal semiconductor chip 200.

In the semiconductor package 1D according to some embodiments, the internal semiconductor chip 200A is not exposed to the outside, and also, the heat dissipation structure 410 is directly on the upper surface 210S of the internal semiconductor chip 200. Accordingly, heat dissipation characteristics and reliability of the semiconductor package 1D according to some embodiments may be improved.

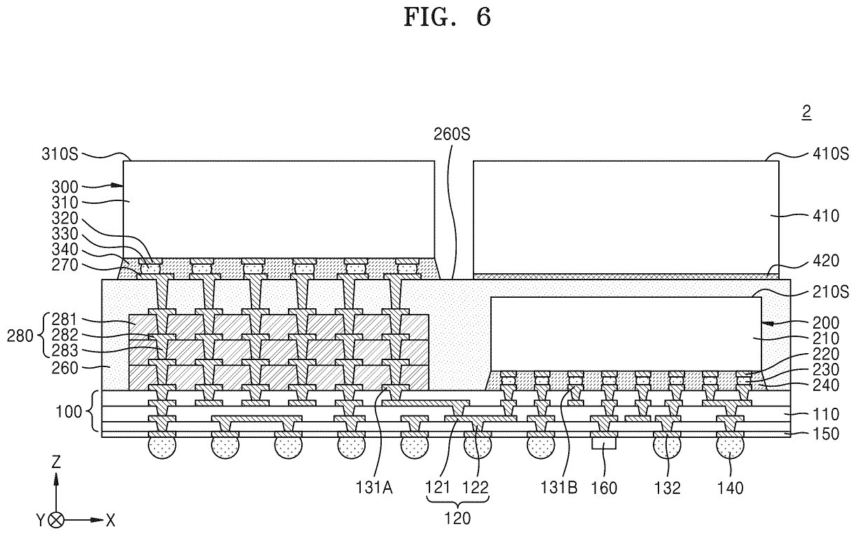

FIG. 6 is a cross-sectional view illustrating a semiconductor package according to one or more example embodiments. Descriptions similar to the descriptions given with reference to FIGS. 1A to 5B may be omitted.

Referring to FIG. 6, the semiconductor package 2 may include a lower redistribution structure 100, an internal semiconductor chip 200, a core layer 280, an encapsulant 260, an external semiconductor device 300, and a heat dissipation structure 410. The semiconductor package 2 may be an FOPLP.

The core layer 280 may include a core insulating layer 281, core wiring layers 282, and core vias 283. The core layer 280 may be on a side of the internal semiconductor chip 200 spaced apart from the internal semiconductor chip 200, and arranged on the lower redistribution structure 100. A portion of an upper surface and a side surfaces of the core layer 280 may be surrounded by the encapsulant 260. The core wiring layers 282 and the core vias 283 may be arranged to electrically connect upper and lower surfaces of the core layer 280. The core wiring layers 282 may be inside the core insulating layer 281 but are not limited thereto. Among the core wiring layers 282, the core wiring layers 282 exposed through a lower surface of the core layer 280 may be buried in the core insulating layer 281 and may have a structure corresponding to a manufacturing process. The core insulating layer 281 may be referred to as a base substrate.

When an arrangement of the core vias 283 having upper surfaces arranged on the upper surface 260S of the encapsulant 260 does not match an arrangement of the plurality of second connection pads 320 included in the external semiconductor device 300, the plurality of upper trace pads 270 may have extend toward the plurality of second connection pads 320 such that the core vias 283 and the second connection pad 320, which have to be connected to each other, are connected to each other.

The plurality of upper trace pads 270 may be respectively connected to the plurality of second connection pads 320 of the external semiconductor device 300. The plurality of upper trace pads 270 may be respectively and electrically connected to the core vias 283. However, the plurality of second connection pads 320 of the external semiconductor device 300 that are to be electrically connected to the core vias 283 may be misaligned with core vias on a horizontal plane. That is, the plurality of second connection pads 320 that are to be electrically connected to the core vias 283 may be offset in the horizontal direction from the core vias 283 corresponding thereto. The plurality of upper trace pads 270 may extend from the core vias 283 to be respectively provided below the plurality of second connection pads 320, and a plurality of second connection members 330 may be respectively provided between the plurality of upper trace pads 270 and the plurality of second connection pads 320, such that the plurality of second connection pad 320 and the core vias 283, which are horizontally offset from each other, are respectively and electrically connected to the core vias 283.

The core insulating layer 281 may include an insulating material (for example, a thermosetting resin such as an epoxy resin), or a thermoplastic resin such as polyimide and may further include an inorganic filler. Alternatively, the core insulating layer 281 may include a resin impregnated into a core material, such as glass fiber (glass cloth or glass fabric) along with an inorganic filler, for example, prepreg, Ajinomoto build-up film (ABF), FR-4, or bismaleimide triazine (BT). The core insulating layer 281 may be a multi-layer substrate including a plurality of layers.

The semiconductor package 2 according to some embodiments does not have an upper redistribution structure, and the external semiconductor device 300 is mounted on the encapsulant 260. Accordingly, the heat generated by the internal semiconductor chip 200 may be smoothly dissipated. Also, by providing the heat dissipation structure 410 on the upper surface 260S of the encapsulant 260 above the internal semiconductor chip 200, the heat generated by the internal semiconductor chip 200 may be transferred to the heat dissipation structure 410, and thus, heat dissipation of the internal semiconductor chip 200 may be made more smoothly. Accordingly, heat dissipation characteristics of the semiconductor package 2 according to some embodiments may be improved.

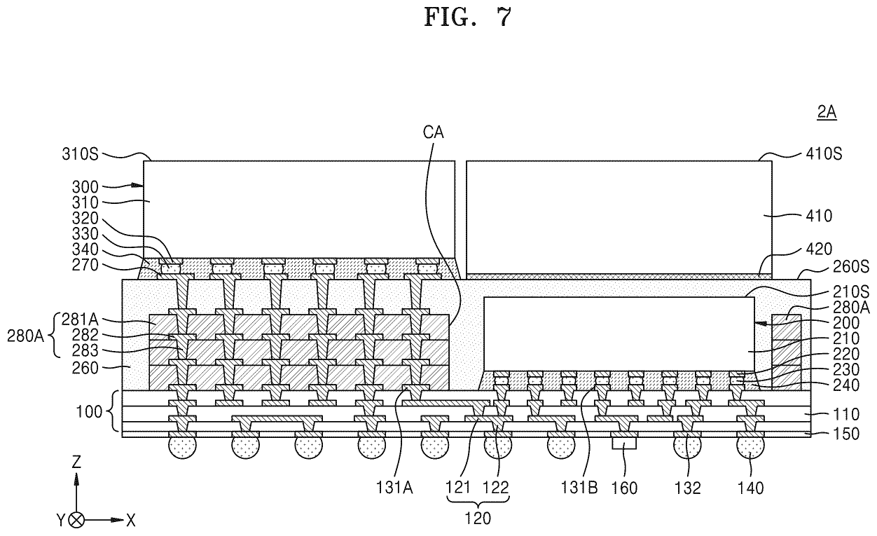

FIG. 7 is a cross-sectional view illustrating a semiconductor package according to one or more example embodiments. Descriptions similar to the descriptions given with reference to FIGS. 1A to 6 may be omitted.

Referring to FIG. 7, the semiconductor package 2A may include a lower redistribution structure 100, an internal semiconductor chip 200, a core layer 280A, an encapsulant 260, an external semiconductor device 300, and a heat dissipation structure 410.

The core layer 280A may include a core insulating layer 281A, core wiring layers 282, and core vias 283. The core layer 280A may be on a side of the internal semiconductor chip 200 spaced apart from the internal semiconductor chip 200, and may be on the lower redistribution structure 100. The core layer 280A may include a through-hole CA that vertically penetrates the core layer 280A such that the internal semiconductor chip 200 is provided in the through-hole CA of the core layer 280A. As illustrated in FIG. 7, the through-hole CA may be provided in the core layer 280A, the core layer 280A provided relative to one side (e.g., the left side as depicted in FIG. 7) of the internal semiconductor chip 200 in the through-hole CA may include the core wiring layers 282 and the core vias 283, and the core layer 280 provided relative to another side (e.g., the right side as depicted in FIG. 7) of the internal semiconductor chip 200, may not include the core wiring layers 282 and the core vias 283 but may include only the core insulating layer 281A. That is, the through-hole CA provided in the core layer 280A may be formed near a side surface of the core layer 280A without being formed in the center of the core layer 280A (i.e., the through-hole CA may be offset from a center of the core layer 280 as measured from the Z-axis shown in FIG. 7). Accordingly, an arrangement of the internal semiconductor chip 200 in the through-hole CA may also be deviated from the center of the lower redistribution structure 100 to the outside.

The core wiring layers 282, which are relative to one side of the internal semiconductor chip 200, and arranged on the core layer 280A, and the core vias 283 may be respectively and electrically connected to the plurality of upper trace pads 270 through vias penetrating the encapsulant 260.

In the semiconductor package 2A according to some embodiments, the heat generated by the internal semiconductor chip 200 may be transferred to the heat dissipation structure 410, and thus, heat dissipation of the internal semiconductor chip 200 may be made more smoothly. Accordingly, heat dissipation characteristics of the semiconductor package 2A according to some embodiments may be improved.

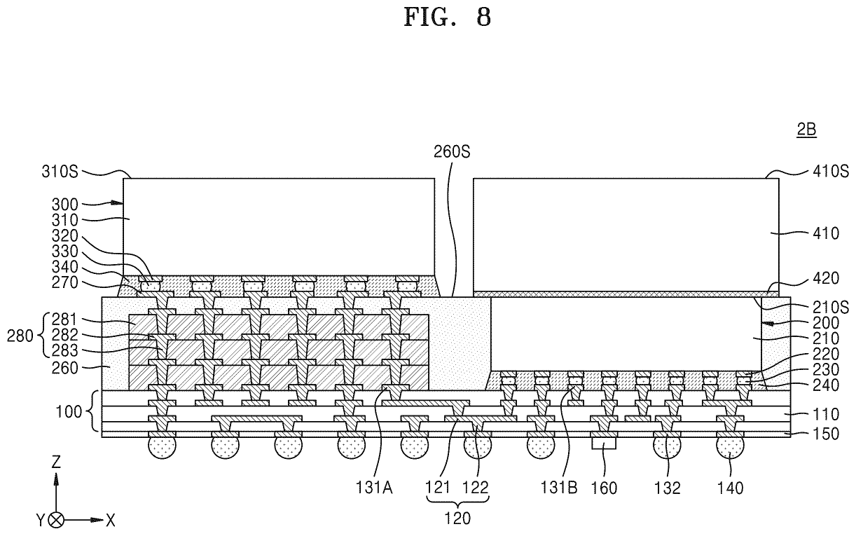

FIG. 8 is a cross-sectional view illustrating a semiconductor package according to one or more example embodiments. Descriptions similar to the descriptions given with reference to FIGS. 1A to 7 may be omitted.

Referring to FIG. 8, an upper surface 260S of an encapsulant 260 of the semiconductor package 2B may be substantially coplanar with an upper surface 210S of an internal semiconductor chip 200. That is, the upper surface 210S of the internal semiconductor chip 200 may be exposed from the upper surface 210S of the encapsulant 260. Accordingly, a heat dissipation structure 410 may be on the upper surface 210S of the internal semiconductor chip 200 through a heat transfer layer 420. In the semiconductor package 2B according to some embodiments, a vertical level of the upper surface 260S of the encapsulant 260 may be equal to the upper surface 210S of the internal semiconductor chip 200 as in the semiconductor package 2 described above, or the encapsulant 260 may be formed to cover the upper surface 210S of the internal semiconductor chip 200 and then the upper surface 210S of the internal semiconductor chip 200 may be exposed by using a method, such as chemical mechanical polishing (CMP).

In the semiconductor package 2B according to some embodiments, the external semiconductor device 300 may be mounted without an upper redistribution structure, and thus, the heat generated by the internal semiconductor chip 200 may be smoothly dissipated. Also, by providing the heat dissipation structure 410 on the upper surface 210S of the internal semiconductor chip 200, the heat generated by the internal semiconductor chip 200 may be transferred to the heat dissipation structure 410, and thus, heat dissipation of the internal semiconductor chip 200 may be made more smoothly. Accordingly, heat dissipation characteristics of the semiconductor package 2B according to some embodiments may be improved.

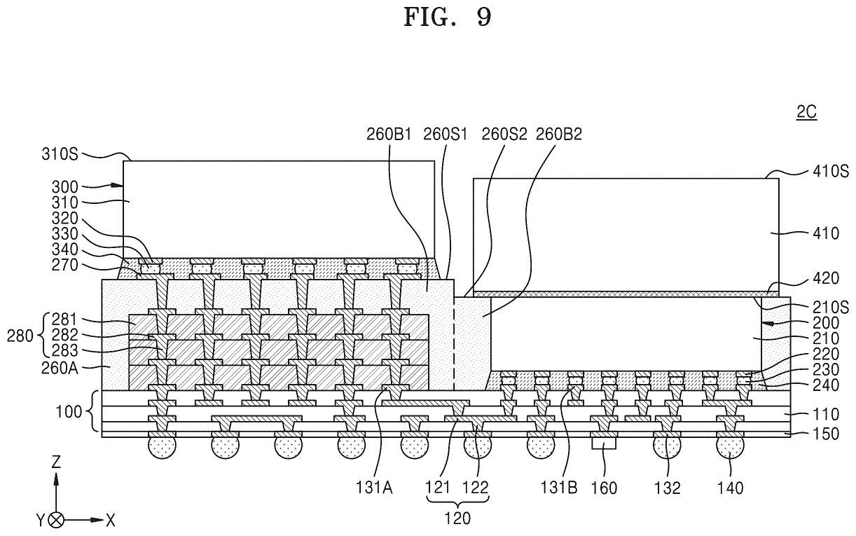

FIG. 9 is a cross-sectional view illustrating a semiconductor package according to one or more example embodiments. Descriptions similar to the descriptions given with reference to FIGS. 1A to 8 may be omitted.

An encapsulant 260A of the semiconductor package 2C according to some embodiments may be formed by forming an initial encapsulant and then removing a portion to be formed as a second encapsulant 260B2 such that a vertical level of the first upper surface 260S1 of the first encapsulant 260B1 is different from a vertical level of the second upper surface 260S2 of the second encapsulant 260B2.

By providing the heat dissipation structure 410 directly on the internal semiconductor chip 200 of the semiconductor package 2C according to some embodiments, the heat generated by the internal semiconductor chip 200 may be more effectively transferred to the heat dissipation structure 410, and thus, the heat generated by the internal semiconductor chip 200 may be more easily dissipated. Accordingly, heat dissipation characteristics of the semiconductor package 2C according to some embodiments may be improved.

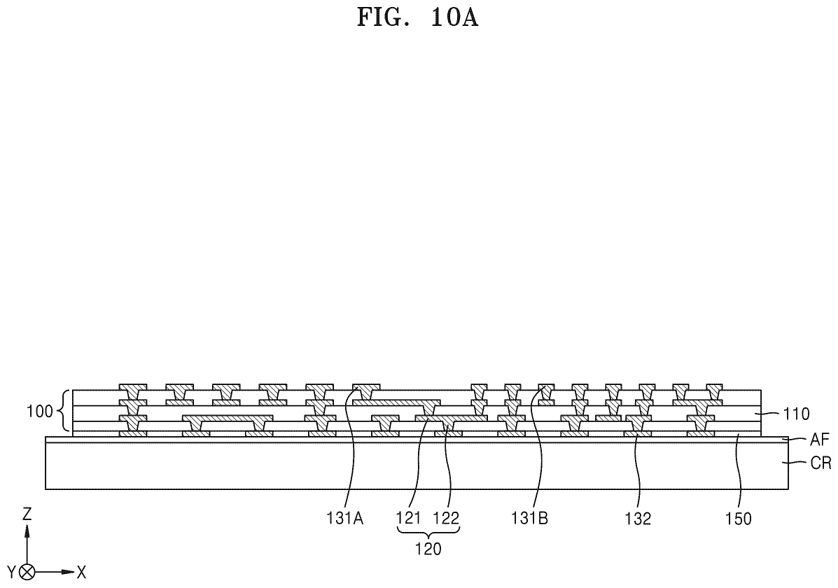

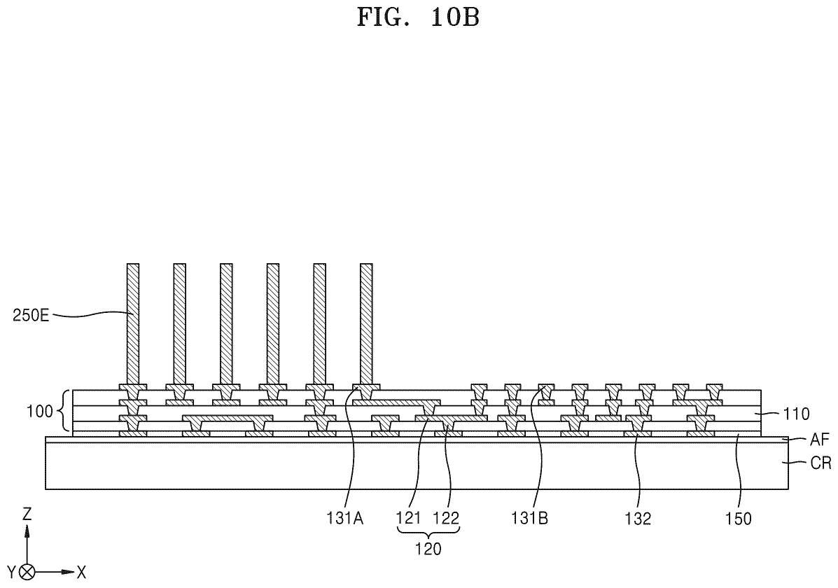

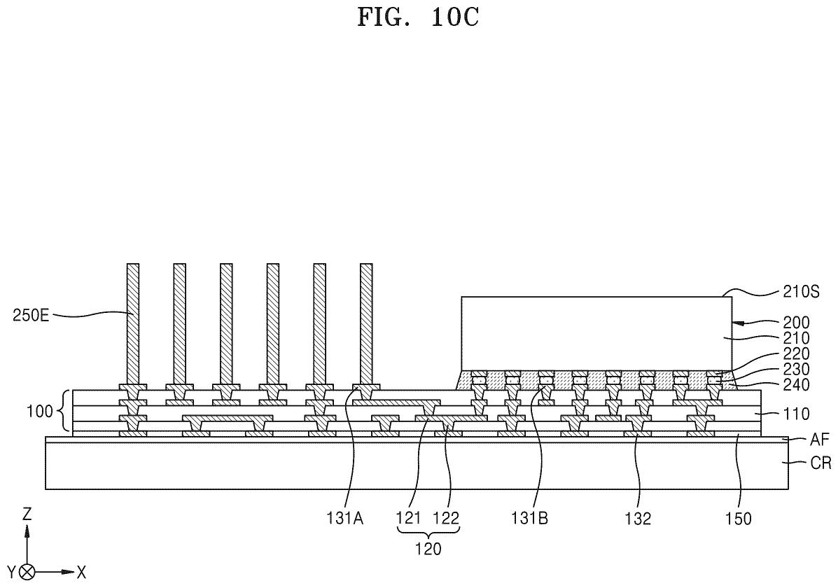

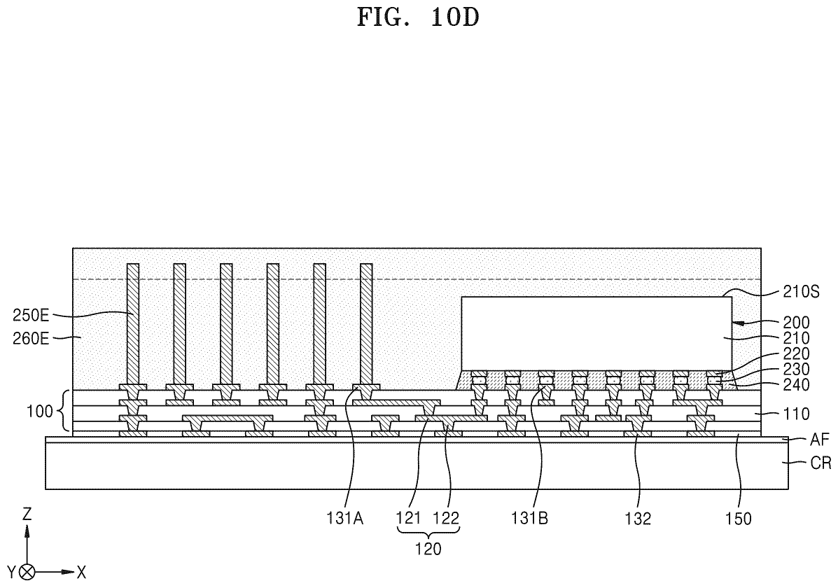

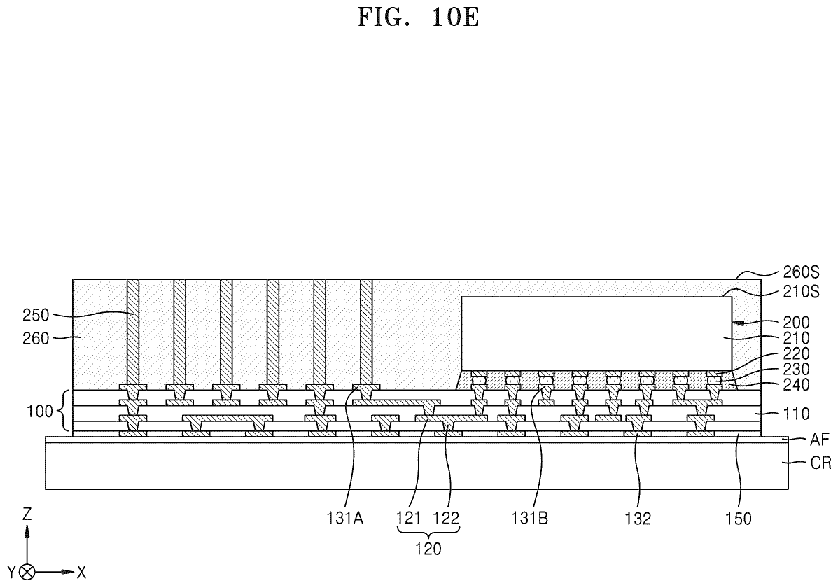

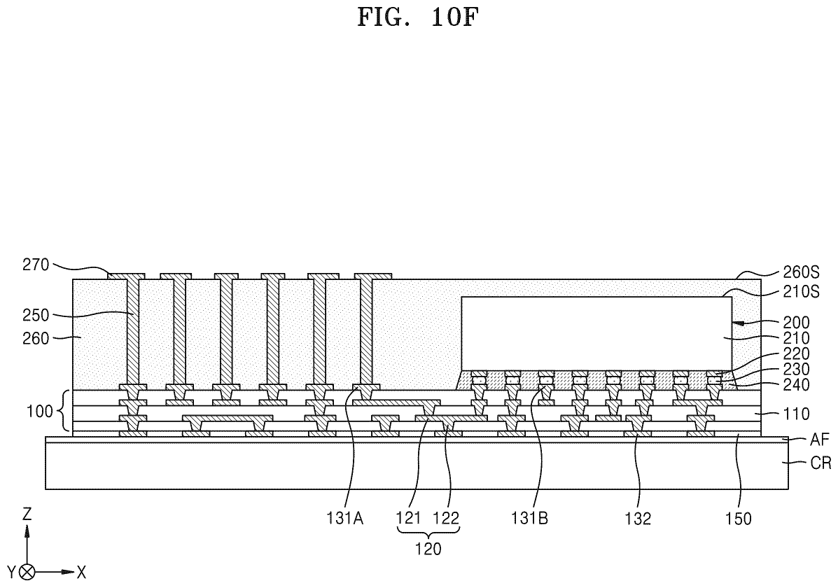

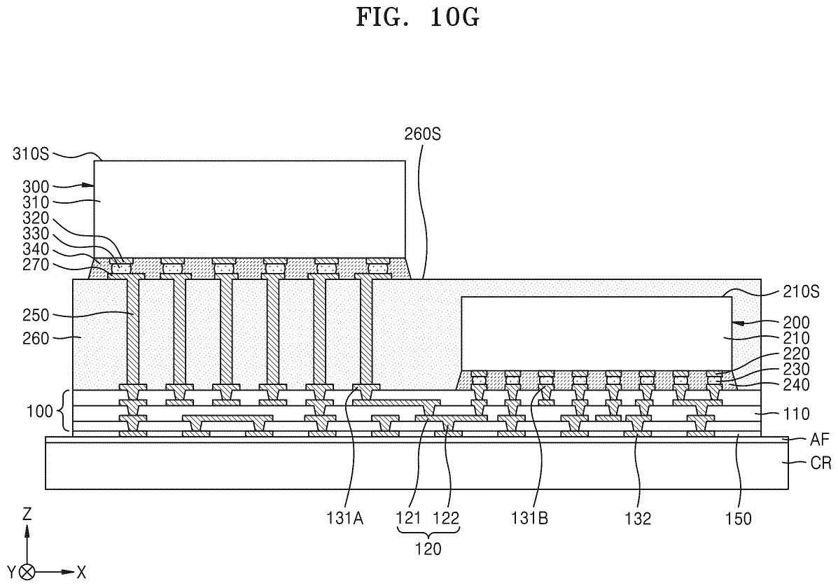

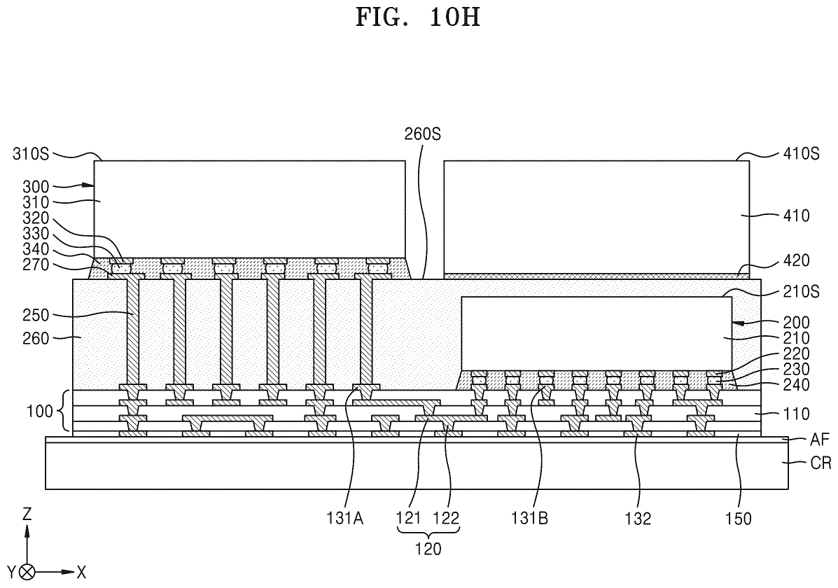

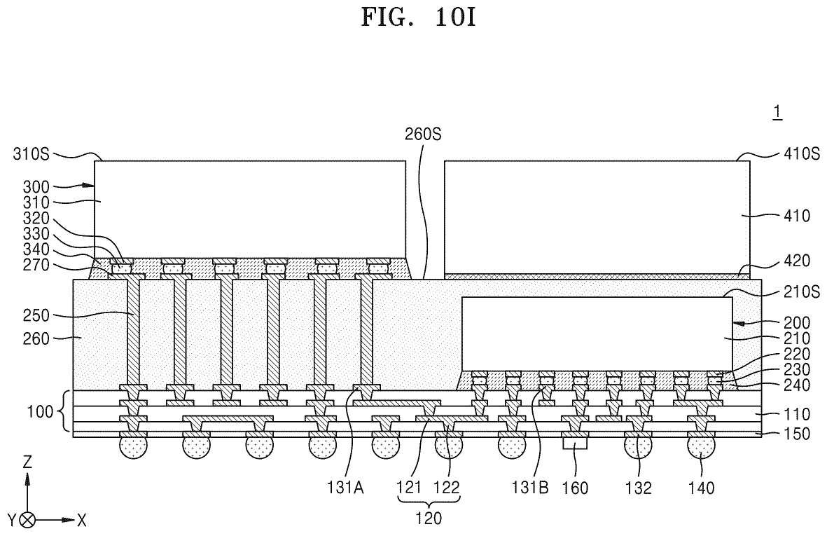

FIGS. 10A to 10I are cross-sectional views sequentially illustrating a method of manufacturing a semiconductor package, according to one or more example embodiments. Descriptions similar to the descriptions given with reference to FIGS. 1A to 9 may be omitted.

Referring to FIGS. 10A to 10C, the lower redistribution structure 100 may be formed on an attachment film AF on a carrier CR. A plurality of conductive posts 250E may be respectively formed on a plurality of first upper connection pads 131A on the lower redistribution structure 100. Also, the internal semiconductor chip 200 may be mounted on the lower redistribution structure 100 by a flip chip method, and the internal underfill layer 240 may be formed between the internal semiconductor chip 200 and the lower redistribution structure 100. For example, the internal underfill layer 240 may be formed through a capillary underfill process, and the internal underfill layer 240 may include an epoxy resin.

Referring to FIGS. 10D to 10F, an encapsulant 260E may be formed to cover side surfaces and upper surfaces of the plurality of conductive posts 250E and side surfaces and upper surfaces of the internal semiconductor chip 200. The encapsulant 260E may be a molding member including an EMC and may further include a filler. A portion of the encapsulant 260E and a portion of each of the plurality of conductive posts 250E may be removed along the horizontal dashed line illustrated in FIG. 10D, as illustrated in FIG. 10E. For example, a portion of the encapsulant 260E and a portion of each of the plurality of conductive posts 250E may be removed through CMP. On an upper surface 260S of the encapsulant 260, one upper surface of each of the plurality of conductive posts 250 may be substantially coplanar with the upper surface 260S of the encapsulant 260. On the upper surface 260S of the encapsulant 260, a plurality of upper trace pads 270 may be patterned and formed. The plurality of upper trace pads 270 may be electrically connected to the plurality of conductive posts 250 corresponding thereto.

Referring to FIGS. 10G to 101, the external semiconductor device 300 may be on the encapsulant 260, and a plurality of second connection pads 320 may be respectively and electrically connected to the plurality of upper trace pads 270 by a plurality of second connection members 330. Similar to the internal underfill layer 240, an external underfill layer 340 may be formed between the external semiconductor device 300 and the encapsulant 260. The heat dissipation structure 410 may be on a side of the external semiconductor device 300 spaced apart from the internal semiconductor chip 200 and may be on the upper surface 260S of the encapsulant 260. The heat dissipation structure 410 may be on the upper surface 260S of the encapsulant 260 through the heat transfer layer 420. Thereafter, the attachment film AF and the carrier CR may be removed, the passive element 160 may be on some of the plurality of external connection pads 132, and the plurality of external connection terminals 140 may be attached to the other external connection pads 132. Thus, the semiconductor package 1 may be formed as shown in FIG. 10I.

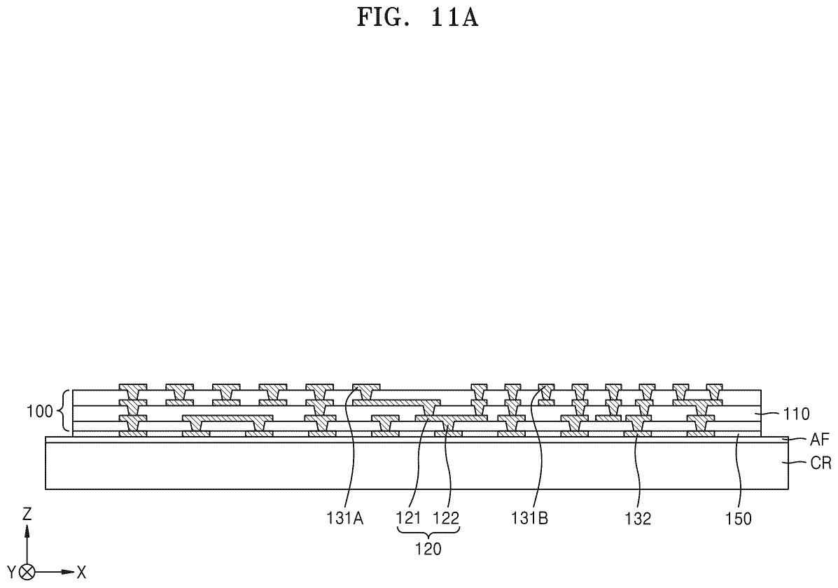

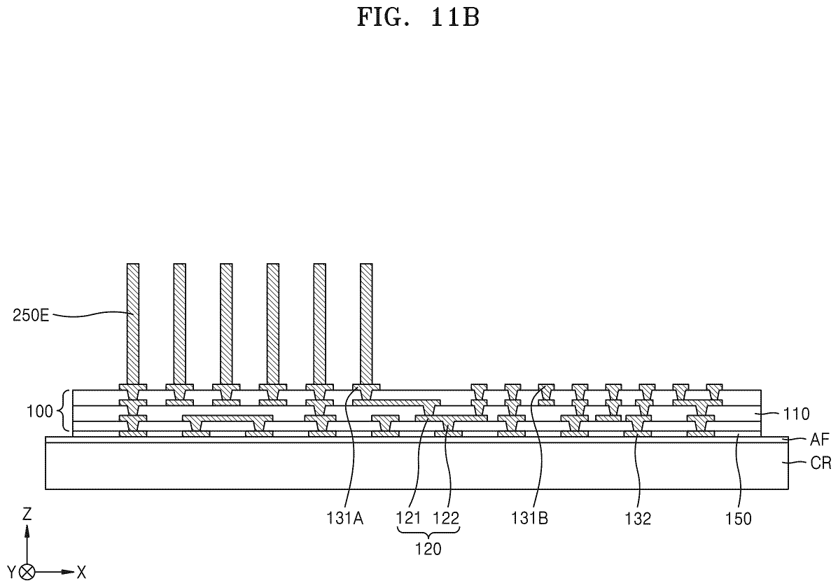

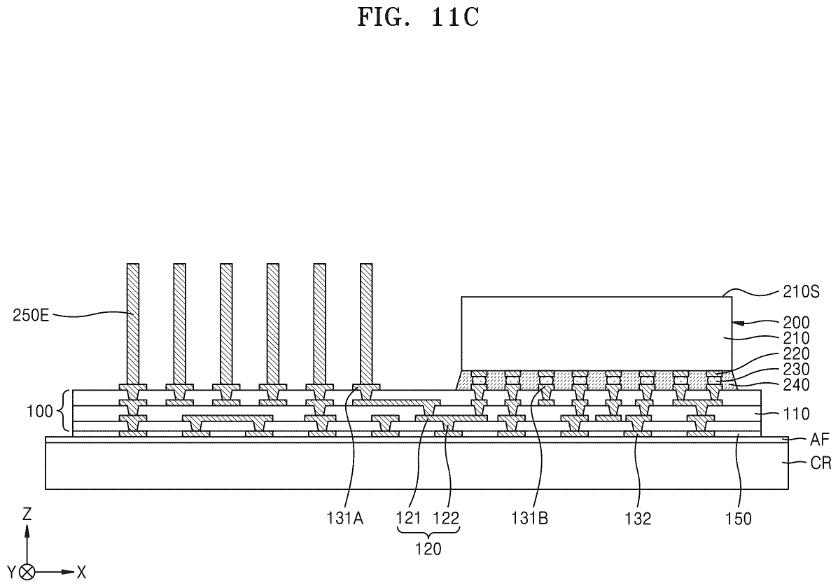

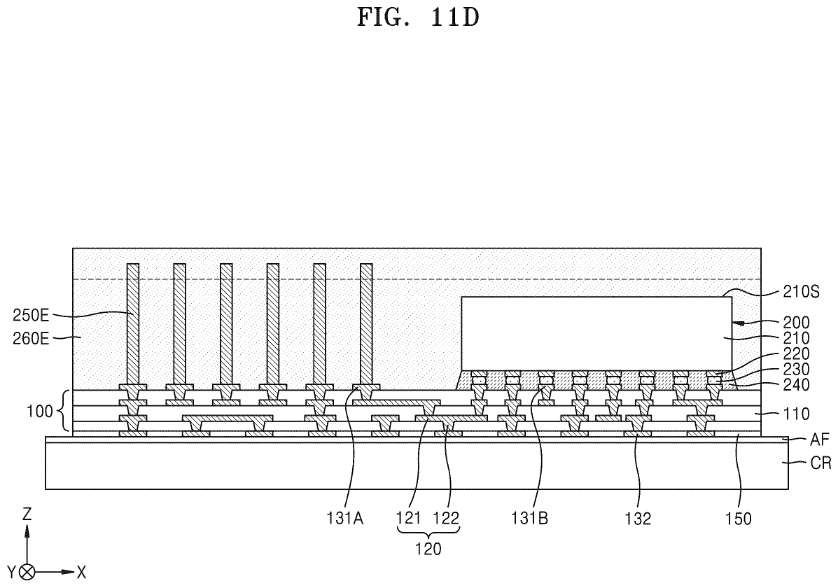

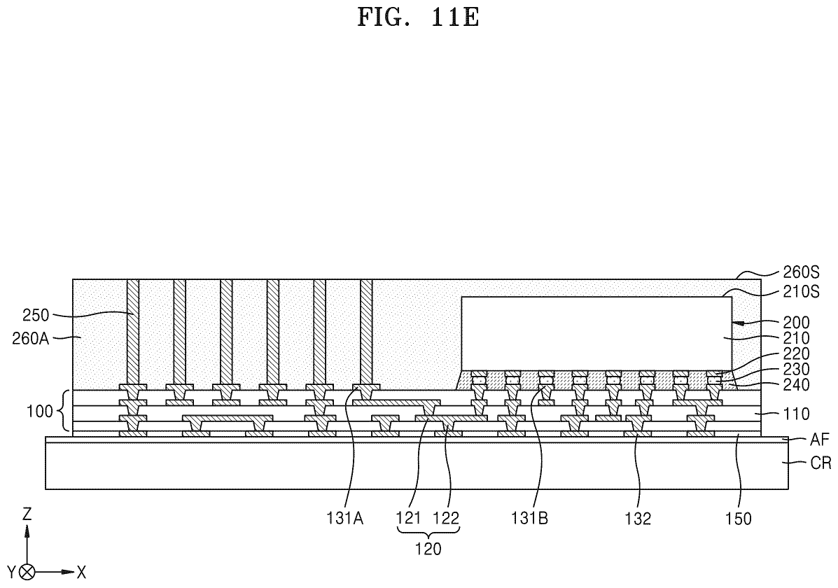

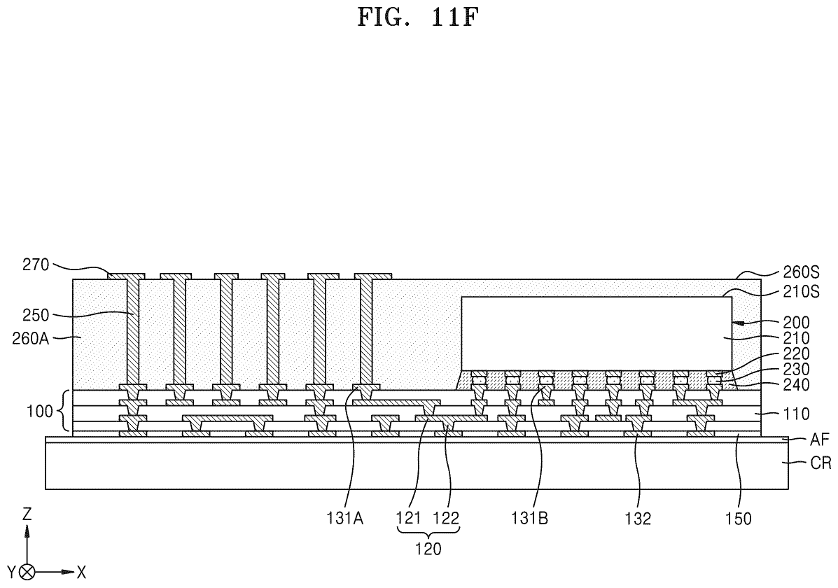

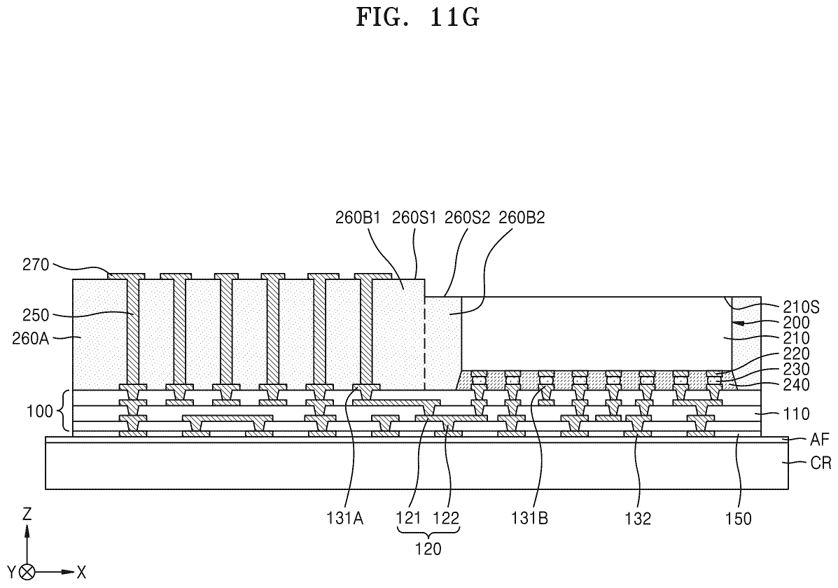

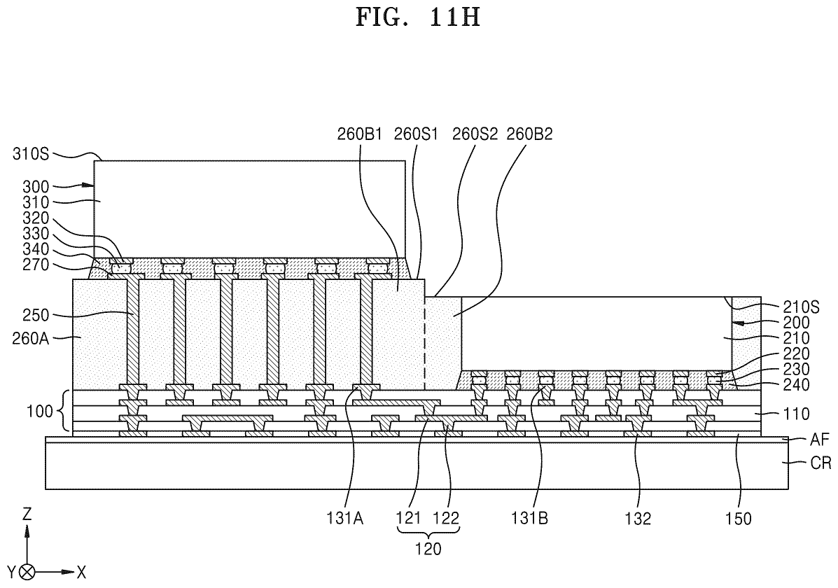

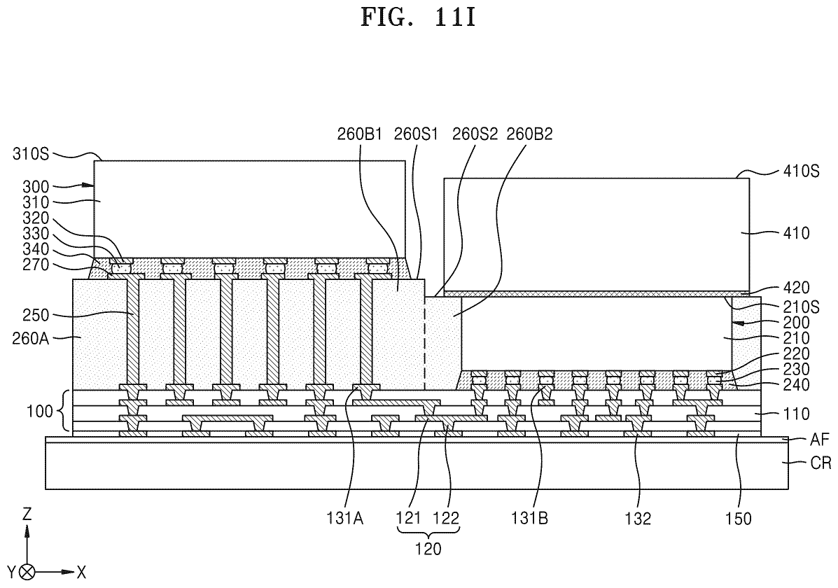

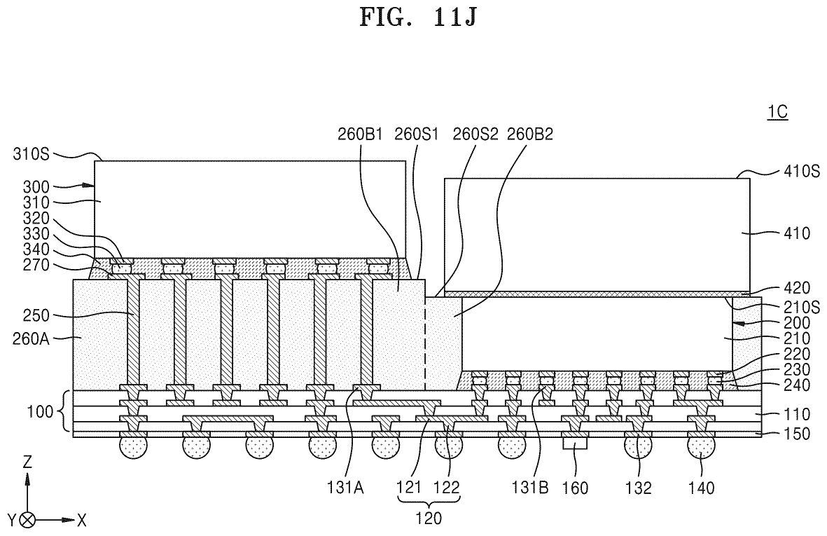

FIGS. 11A to 11J are cross-sectional views sequentially illustrating a method of manufacturing a semiconductor package, according to one or more example embodiments. Descriptions similar to the descriptions given with reference to FIGS. 1A to 10I may be omitted.

Descriptions of FIGS. 11A to 11F overlap the descriptions of FIGS. 10A to 10F described above, and accordingly, redundant descriptions thereof may be omitted.

Referring to FIGS. 11G to 11I, by etching or removing a portion of the encapsulant 260A on the side where the internal semiconductor chip 200 is placed, the encapsulant 260A may be divided to have a first upper surface 260S1 and a second upper surface 260S2. As indicated by the vertical dashed line in FIG. 11G, the encapsulant 260A may be divided into a first encapsulant 260B1 and a second encapsulant 260B2, and the first encapsulant 260B1 and the second encapsulant 260B2 may be integrally formed as the encapsulant 260A. A portion of the encapsulant 260A may be removed to expose the upper surface 210S of the internal semiconductor chip 200.

The external semiconductor device 300 may be on the encapsulant 260A, and the plurality of second connection pads 320 may be respectively and electrically connected to the plurality of upper trace pads 270 by the plurality of second connection members 330. Similar to the internal underfill layer 240, the external underfill layer 340 may be between the external semiconductor device 300 and the encapsulant 260A. The heat dissipation structure 410 may be on a side of the external semiconductor device 300 spaced apart from the internal semiconductor chip 200 and may be on the upper surface 210S of the internal semiconductor chip 200 and the second upper surface 260S2 of the second encapsulant 260B2. The heat dissipation structure 410 may be provided on the upper surface 210S of the internal semiconductor chip 200 and the second upper surface 260S2 of the second encapsulant 260B2 through the heat transfer layer 420. Thereafter, the attachment film AF and the carrier CR may be removed, the passive element 160 may be on a portion of each of the plurality of external connection pads 132, and the plurality of external connection terminals 140 may be respectively attached to the other external connection pads 132. Thus, the semiconductor package 1C may be formed as shown in FIG. 11J.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a lower redistribution structure;
an internal semiconductor chip on the lower redistribution structure and comprising first connection pads on a lower surface of the internal semiconductor chip;
conductive posts electrically connected to the lower redistribution structure;
an encapsulant surrounding a side surface of each of the conductive posts, surrounding a side surface of the internal semiconductor chip, and covering an upper surface of the internal semiconductor chip;
upper trace pads on the encapsulant and respectively connected to ends of the conductive posts;
an external semiconductor device on the encapsulant, the external semiconductor device comprising second connection pads on a lower surface of the external semiconductor device and respectively connected to the upper trace pads;
a heat dissipation structure on the encapsulant and laterally spaced apart from the external semiconductor device; and
a heat transfer layer on a lower surface of the heat dissipation structure, the heat transfer layer comprising a thermal interface material,
wherein the heat dissipation structure is above the internal semiconductor chip.

2. The semiconductor package of claim 1, wherein the conductive posts are laterally spaced apart from a first side of the internal semiconductor chip and are not provided relative to a second side of the internal semiconductor chip that is opposite the first side of the internal semiconductor chip.

3. The semiconductor package of claim 2, wherein upper surfaces of the conductive posts are substantially coplanar with an upper surface of the encapsulant, and
wherein at least some of the upper trace pads horizontally extend on the encapsulant from the conductive posts.

4. The semiconductor package of claim 3, wherein at least one second connection pad of the second connection pads is laterally offset from at least one conductive post of the conductive posts that is connected to the at least one second connection pad.

5. The semiconductor package of claim 4, wherein the upper surface of the internal semiconductor chip is substantially coplanar with the upper surface of the encapsulant,
wherein the heat dissipation structure is on the upper surface of the internal semiconductor chip, and
wherein the heat transfer layer is between the internal semiconductor chip and the heat dissipation structure.

6. The semiconductor package of claim 4, wherein the encapsulant comprises a first encapsulant and a second encapsulant which are integrally formed,
wherein an upper surface of the first encapsulant is at a vertical level that is higher than a vertical level of an upper surface of the second encapsulant,
wherein the upper trace pads are on the upper surface of the first encapsulant, and
wherein the upper surface of the second encapsulant is substantially coplanar with the upper surface of the internal semiconductor chip.

7. The semiconductor package of claim 6, wherein a horizontal width of the heat dissipation structure is greater than a horizontal width of the internal semiconductor chip.

8. The semiconductor package of claim 7, wherein a vertical level of an upper surface of the heat dissipation structure is substantially equal to a vertical level of an upper surface of the external semiconductor device.

9. The semiconductor package of claim 6, wherein the first encapsulant contacts a portion of a side surface of the heat dissipation structure, and
wherein a portion of the external semiconductor device overlaps an with a portion of the internal semiconductor chip.

10. The semiconductor package of claim 9, wherein the heat dissipation structure is on a portion of the upper surface of the internal semiconductor chip and on a portion of the upper surface of the second encapsulant, and
wherein a remaining portion of the upper surface of the internal semiconductor chip is covered by the first encapsulant.

11. The semiconductor package of claim 1, wherein the internal semiconductor chip comprises logic elements, and
wherein the external semiconductor device comprises a memory chip.

12. The semiconductor package of claim 1, wherein the heat dissipation structure comprises at least one of aluminum (Al), copper (Cu), titanium (Ti), nickel (Ni), iron (Fe), cobalt (Co), palladium (Pd), platinum (Pt), gold (Au), lead (Pb), silver (Ag), carbon (C), tin (Sn), tungsten (W), and chromium (Cr), an alloy including a combination thereof, and silicon.

13. A semiconductor package comprising:
a lower redistribution structure;
an internal semiconductor chip on the lower redistribution structure and comprising first connection pads on a lower surface of the internal semiconductor chip;
a core layer on the lower redistribution structure and laterally spaced apart from the internal semiconductor chip, the core layer comprising a core insulating layer, core vias passing through the core insulating layer, and core wiring layers;
an encapsulant at least partially surrounding the internal semiconductor chip and the core layer;
upper trace pads on the encapsulant;
an external semiconductor device on the encapsulant, the external semiconductor device comprising second connection pads on a lower surface of the external semiconductor device and respectively connected to the upper trace pads;
a heat dissipation structure on the encapsulant and laterally spaced apart from the external semiconductor device; and
a heat transfer layer on a lower surface of the heat dissipation structure, the heat transfer layer comprising a thermal interface material,
wherein the heat dissipation structure is above the internal semiconductor chip.

14. The semiconductor package of claim 13, wherein the core layer comprises a first portion relative to a first side of the internal semiconductor chip and a second portion relative to a second side of the internal semiconductor chip that is opposite to the first side of the internal semiconductor chip, wherein the core vias and the core wiring layers are in the first portion of the core layer, and
wherein the core vias and the core wiring layers are not in the second portion of the core layer.

15. The semiconductor package of claim 14, wherein at least some of the upper trace pads horizontally extend on the encapsulant from upper surfaces of the core vias, and
wherein at least one second connection path of the second connection pads is laterally offset from an upper surface of at least one core via of the core vias that are connected to the second connection pads.

16. The semiconductor package of claim 15, wherein the core insulating layer is laterally spaced apart from the internal semiconductor chip and surrounds the first side and the second side of the internal semiconductor chip.

17. The semiconductor package of claim 15, wherein an upper surface of the internal semiconductor chip is substantially coplanar with an upper surface of the encapsulant,
wherein the heat dissipation structure is on the upper surface of the internal semiconductor chip, and
wherein the heat transfer layer is between the internal semiconductor chip and the heat dissipation structure.

18. The semiconductor package of claim 15, wherein the encapsulant comprises a first encapsulant and a second encapsulant which are integrally formed,
wherein an upper surface of the first encapsulant is at a vertical level that is higher than a vertical level of an upper surface of the second encapsulant,
wherein the upper trace pads are on the upper surface of the first encapsulant, and
wherein the upper surface of the second encapsulant is substantially coplanar with the upper surface of the internal semiconductor chip.

19. The semiconductor package of claim 18, wherein a horizontal width of the heat dissipation structure is greater than a horizontal width of the internal semiconductor chip, and
wherein a vertical level of an upper surface of the heat dissipation structure is lower than or equal to a vertical level of an upper surface of the external semiconductor device.

20. A semiconductor package comprising:
a lower redistribution structure;
an internal semiconductor chip on the lower redistribution structure and comprising first connection pads on a lower surface of the internal semiconductor chip;
conductive posts connected to the lower redistribution structure;
an encapsulant surrounding a side surface of each of the conductive posts, surrounding a side surface of the internal semiconductor chip, and covering an upper surface of the internal semiconductor chip;
upper trace pads on the encapsulant and respectively connected to ends of the conductive posts;
an external semiconductor device on the encapsulant, the external semiconductor device comprising second connection pads on a lower surface of the external semiconductor device and respectively connected to the upper trace pads;
a heat dissipation structure on the encapsulant and laterally spaced apart from the external semiconductor device; and
a heat transfer layer on a lower surface of the heat dissipation structure, the heat transfer layer comprising a thermal interface material,
wherein the heat dissipation structure is above the internal semiconductor chip,
wherein the conductive posts are laterally spaced apart from a first side of the internal semiconductor chip and are not provided relative to a second side of the internal semiconductor chip that is opposite the first side of the internal semiconductor chip,
wherein an upper surface of each of the conductive posts is coplanar with an upper surface of the encapsulant,
wherein at least some of the upper trace pads horizontally extend on the encapsulant from the conductive posts,
wherein at least one second connection pad of the second connection pads is laterally offset from at least one conductive post of the conductive posts that is connected to the at least one second connection pad,
wherein the encapsulant comprises a first encapsulant and a second encapsulant which are integrally formed,
wherein an upper surface of the first encapsulant is at a vertical level that is higher than a vertical level of an upper surface of the second encapsulant,
wherein the upper trace pads are on the upper surface of the first encapsulant,
wherein the upper surface of the second encapsulant is coplanar with the upper surface of the internal semiconductor chip,
wherein a horizontal width of the heat dissipation structure is greater than a horizontal width of the internal semiconductor chip, and
wherein a vertical level of an upper surface of the heat dissipation structure is lower than or equal to a vertical level of an upper surface of the external semiconductor device.
